(19) United States
(12) Patent Application Publication
(10) Pub. No.: US 2021/0218391 A1
(43) Pub. Date: Jul. 15, 2021

(54) COMPARATOR CIRCUIT

(71) Applicant: KABUSHIKI KAISHA TOKAI-RIKA-DENKI-SEISAKUSHO, Niwa-gun (JP)

(72) Inventor: Keigo KAGIMOTO, Niwa-gun (JP)

(21) Appl. No.: 17/142,336

(22) Filed: Jan. 6, 2021

(30) Foreign Application Priority Data
Jan. 9, 2020 (JP) 2020-002104

(51) Int. Cl. H03K 5/24; G05F 3/26

(52) U.S. Cl. CPC H03K 5/2472; G05F 3/262

(57) ABSTRACT

A comparator circuit is provided, including an input current generation section configured to generate an input current based on an input voltage, a reference current generation section configured to generate a reference current based on a reference voltage, a first current-voltage conversion section configured to convert the input current to a comparison-target voltage, a second current-voltage conversion section configured to convert the reference current to a threshold voltage, and a comparison section configured to compare the comparison-target voltage against the threshold voltage. The input current generation section includes a first transistor having a gate and a drain that are connected together, and the input voltage is input to the drain of the first transistor via a resistor.

### CROSS-REFERENCE TO RELATED APPLICATION

This application is based on and claims priority under 35 USC 119 from Japanese Patent Application No. 2020-002104 filed on Jan. 9, 2020, the disclosure of which is incorporated by reference herein.

### BACKGROUND

### Technical Field

The present disclosure relates to a comparator circuit.

Japanese Patent Application Laid-Open (JP-A) No. 2003-207527 is an example of known literature relating to a comparator circuit that sets a reference voltage to a comparatively high potential. A high voltage detection circuit according to JP-A No. 2003-207527 performs detection of a high voltage output from a high voltage generation circuit. A high voltage stepdown circuit steps down the output voltage of the high voltage generation circuit and outputs a stepped-down voltage. A reference voltage generation circuit uses the output of the high voltage generation circuit as a power source to output the reference voltage. The comparator circuit compares the output of the high voltage stepdown circuit against the output of the reference voltage generation circuit so as to control a high voltage level.

FIG. 3 illustrates a comparator circuit 100 according to related technology as an example of a basic comparator circuit that may be employed in the high voltage detection circuit according to JP-A No. 2003-207527. As illustrated in FIG. 3, the comparator circuit 100 is configured including N-type metal oxide semiconductor (MOS) transistors QN11, QN12, P-type MOS transistors QP11, QP12, an inverter IN2, and a current source Ic An input voltage Yin is input to a gate of the P-type MOS transistor OP11, and a reference voltage Vref is input to a gate of the P-type MOS transistor QP12. The inverter IN2 has an output buffer function, and the output of the inverter IN2 is an output voltage Vout. Note that the N-type MOS transistors QN11, QN12 and the P-type MOS transistors QP11, QP12 of the comparator circuit 100 are connected to a high voltage power source VPH that has a. relatively high voltage, and the inverter 1N2 is connected to a low voltage power source VPL with a relatively low voltage. Namely, the comparator circuit 100 includes a level shifter function.

Discussion follows regarding operation of the comparator circuit 100 using specific example values for the power source voltages and the input voltage. Suppose the voltage of the low voltage power source VPL is 5V, and a gate-source withstand voltage <Vgs> (a maximum voltage value that can be applied between the gate and the source) of the P-type MOS transistor QP11 serving as an input transistor is 5V. The 5V value of the gate-source withstand voltage <Vgs> is a withstand voltage at which circuitry from the inverter IN2 onward that uses the low voltage power source VPL as its power source operates without issue.

A case is now considered in which the high voltage power source VPH with a voltage of 16V is connected to the comparator circuit 100. In such a case, the reference voltage Vref max for example be set to 8V. In many cases, an input circuit with such conditions will demand an input voltage Yin at either a low level (hereafter referred to as “L”) of 0V or a high level (hereafter referred to as “H”) of 16V However, when the input voltage Vin is input at L (=0V), a voltage of 16V is applied as the gate-source voltage Vgs of the P-type MOS transistor QP11. The gate-source voltage Vgs exceeds the gate-source withstand voltage <Vgs>as a result, in a phenomenon not enabling a circuit to be established. Although this phenomenon is obviously dependent on the value of the gate-source withstand voltage <Vgs>, the gate-source withstand voltage <Vgs> is generally lower than, for example, a drain-source withstand voltage <Vds>.

### SUMMARY

In consideration of the above circumstances, the present disclosure relates to the provision of a comparator circuit capable of accommodating a wider dynamic range of input.

A comparator circuit according to a first aspect of the present disclosure includes an input current generation section configured to generate an input current based on an input voltage, a reference current generation section configured to generate a reference current based on a reference voltage, a first current-voltage conversion section configured to convert the input current to a comparison-target voltage, a second current-voltage conversion section configured to convert the reference current to a threshold voltage, and a comparison section configured to compare the comparison-target voltage against the threshold voltage. The input current generation section includes a first transistor having a gate and a drain that are connected together, and the input voltage is input to the drain of the first transistor via a resistor.

In the comparator circuit according to the first aspect, the input current generation section includes the first transistor of which the gate and the drain are connected together, and the input voltage is input to the drain of the first transistor via the resistor. This enables the provision of a comparator circuit capable of accommodating a wider dynamic range of input.

In a comparator circuit according to a second aspect of the present disclosure, the input current generation section includes a second transistor that mirrors a current flowing in the first transistor to generate the input current.

In the comparator circuit according to the second aspect, the input current generation section includes the second transistor that mirrors the current flowing in the first transistor to generate the input current. This enables constraints due to the withstand voltage of the first transistor to be relaxed.

In a comparator circuit according to a third aspect of the present disclosure, the input current generation section and the reference current generation section are connected to a first power source having a first voltage, and the first current-voltage conversion section, the second current-voltage conversion section, and the comparison section are connected to a second power source having a second voltage that is lower than the first voltage.

In the comparator circuit according to the third exemplary embodiment, the input current generation section and the reference current generation section are connected to the first power source having the first voltage, and the first current-voltage conversion section, the second current-voltage conversion section, and the comparison section are connected to the second power source having the second voltage that is lower than the first voltage. This enables level conversion to be performed in a simple manner.

In a comparator circuit according to a fourth aspect of the present disclosure, the first current-voltage conversion section performs conversion to the comparison-target voltage based on a current mirroring the input current, and the second current-voltage conversion section performs conversion to the threshold voltage based on a current mirroring the reference current.

In the comparator circuit according to the fourth aspect, the first current-voltage conversion section performs conversion to the comparison-target voltage based on a current mirroring the input current, and the second current-voltage conversion section performs conversion to the threshold voltage based on a current mirroring the reference current. This enables comparison of the input voltage against the reference voltage to be converted into a comparison of the comparison-target voltage against the threshold voltage.

The present disclosure exhibits the excellent advantageous effect of being able to provide a comparator circuit capable of accommodating a wider dynamic range of input.

### BRIEF DESCRIPTION OF DRAWINGS

FIG. 1 is a circuit diagram illustrating an example of a configuration of a comparator circuit according to an exemplary embodiment of the present disclosure;

FIG. 2 is a circuit diagram illustrating current and voltage at various locations of a comparator circuit according to an exemplary embodiment of the present disclosure; and

FIG. 3 is a circuit diagram illustrating a configuration of a comparator circuit according to related technology.

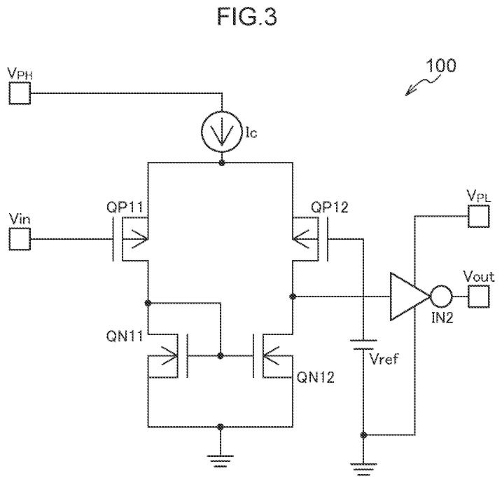

### DETAILED DESCRIPTION

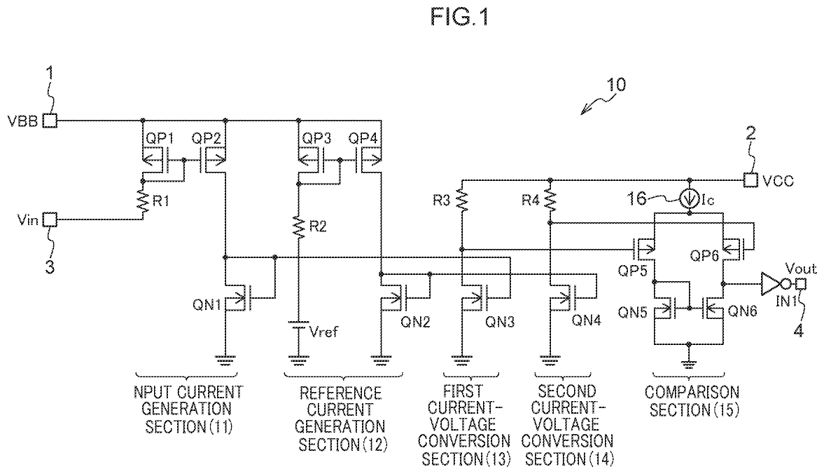

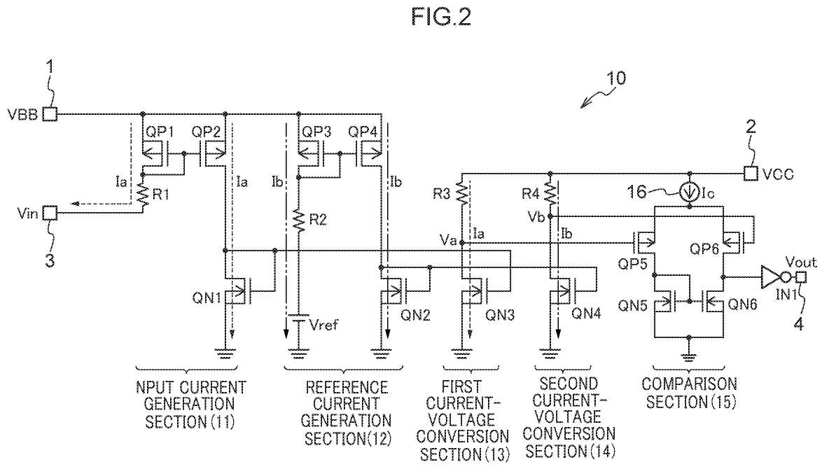

Detailed explanation follows regarding a comparator circuit 10 according to an exemplary embodiment of the present disclosure, with reference to FIG. 1 and FIG. 2. FIG. 1 is a circuit diagram illustrating the comparator circuit 10, and FIG. 2 illustrates current and voltage at various locations of the comparator circuit 10. The comparator circuit 10 is a circuit that for example compares a signal input to a semiconductor integrated circuit against a reference voltage in order to determine a logic level (H or L) of the input signal.

As illustrated in FIG. 1, the comparator circuit 10 according to the present exemplary embodiment is configured including an input current generation section 11, a reference current generation section 12, a first current-voltage conversion section 13, a second current-voltage conversion section 14, and a comparison section 15. A high voltage power source VBB with a relatively high voltage value is connected to a terminal 1, and a low voltage power source VCC with a relatively low voltage value is connected to a terminal 2. An input voltage Vin is input to a terminal 3, and an output voltage Vout is output from a terminal 4. Note although the voltage value of the high voltage power source VBB is set to 16V and the voltage value of the low voltage power source VCC is set to 5V as an example in the present exemplary embodiment, the voltage value of the high voltage power source VBB and the voltage value of the low voltage power source VCC are not limited thereto, and appropriate voltage values therefor may be selected according to design conditions and so on of the comparator circuit 10.

Of the above-mentioned sections, the input current generation section 11 and the reference current generation section 12 are connected to the high voltage power source VBB, and the first current-voltage conversion section 13, the second current-voltage conversion section 14, and the comparison section 15 are connected to the low voltage power source VCC. Namely, the comparator circuit 10 includes a level shift function to convert a voltage range for comparison by the comparison section 15 from a voltage range based on the high voltage power source VBB to a voltage range based on the low voltage power source VCC.

The input current generation section 11 includes an N-type MOS transistor QN1, P-type MOS transistors QP1, QP2, and a resistor R1. As illustrated in FIG. 1, the input voltage Vin is input through a drain of the P-type MOS transistor QP1 via the resistor R1. A gate and the drain of the P-type MOS transistor QP1 are connected together (diode-connected). As illustrated in FIG. 2, the current Ia indicates a current flowing in the P-type MOS transistor QP1 due to application of the input voltage Vin. The P-type MOS transistors QP1 and QP2 configure a current mirror circuit, and the current la also flows in the P-type MOS transistor QP2 in the present exemplary embodiment. Namely, in the present exemplary embodiment this current mirror circuit has a mirror ratio of 1:1; however, there is no limitation thereto and the ratio value thereof may be set as appropriate. When a drain-source voltage V of the P-type MOS transistor QP1 is ˜0, the current Ia satisfies Equation 1 below.

Ia=(VBB−Vin)/R1 (Equation 1)

Note that VBB is the voltage value of the high voltage power source VBB and R1 is the resistance value of the resistor R1.

As illustrated in FIG. 1, the reference current generation section 12 is configured including an N-type MOS transistor QN2, P-type MOS transistors QP3, QP4, and a resistor R2. A reference voltage Vref is connected to a drain of the P-type MOS transistor QP3 via the resistor R2. As an example, a specific value of the reference voltage Vref is 8V The diode-connected P-type MOS transistor QP3 and the P-type MOS transistor QP4 configure a current mirror circuit. As illustrated in FIG. 2, Ib indicates a current flowing in the P-type MOS transistor QP3, and this current Ib also flows in the P-type MOS transistor QP4. Namely, in the present exemplary embodiment this current mirror circuit has a mirror ratio of 1:1; however, there is no limitation thereto and the ratio value thereof may be set as appropriate. When a drain-source voltage Vds of the P-type MOS transistor QP3 is ˜0, the current Ib satisfies Equation 2 below.

Ib=(VBB−Vref)/R2 (Equation 2)

Note that R2 is the resistance value of the resistor R2.

As illustrated in FIG. 1, the first current-voltage conversion section 13 is configured including an N-type MOS transistor QN3 and a resistor R3. The N-type MOS transistor QN3 is connected in parallel with the N-type MOS transistor QN1, and mirrors the current flowing in the P-type MOS transistor QP1. Namely, as illustrated in FIG. 2, the current la also flows in the N-type MOS transistor QN3. When a drain-source voltage Vds of the N-type MOS transistor QN3 is ˜0, a voltage Va at a connection point between a drain of the N-type MOS transistor QN3 and the resistor R3 satisfies Equation 3 below

Va=VCC−IaR3 (Equation 3)

Note that VCC is the voltage value of the low voltage power source VCC and R3 is the resistance value of the resistor R3.

The voltage Va is an example of a “comparison-target voltage” according to the present disclosure.

As illustrated in FIG. 1, the second current-voltage conversion section 14 is configured including an N-type MOS transistor QN4 and a resistor R4. The gate of the N-type MOS transistor QN4 has a common connection with a gate of the N-type MOS transistor QN2 and with a source thereof, and mirrors the current flowing in the P-type MOS transistor QP3. Namely, as illustrated in FIG. 2, the current lb also flows in the N-type MOS transistor QN4. When a drain-source voltage Vds of the N-type MOS transistor QN4 is ˜0, a voltage Vb at a connection point between a drain of the N-type MOS transistor QN4 and the resistor R4 satisfies Equation 4 below.

Vb=VCC−IbR4 (Equation 4)

Note that R4 is the resistance value of the resistor R4.

The voltage Vb is an example of a “threshold voltage” according to the present disclosure.

As illustrated in FIG. 1, the comparison section 15 is configured including N-type MOS transistors QNS, QN6, P-type MOS transistors QP5, QP6, and a current source 16 of a current Ic. The comparison section 15 configures a comparator circuit (a comparator) in which an input voltage is input to a gate of the P-type MOS transistor QP5 and a reference voltage is input to a gate of the P-type MOS transistor QP6, and the input voltage and the reference voltage are compared against each other. An inverter IN1 is an output buffer for outputting the output voltage Vout.

In conventional comparator circuits, usually a gate terminal of a MOS transistor configures a section that receives an input signal. However, the rating of the gate terminal is constrained by a gate-drain withstand voltage <Vgs> and so is generally low. Therefore, in cases in which there is a large potential difference between H and L, it is conceivable that the input signal for either level might exceed the rating, thus destroying the MOS transistor. To address this, in the present exemplary embodiment the gate and drain of the P-type MOS transistor QP1 applied with the input voltage Vin are connected together, and the input voltage Vin is input to the drain of the P-type MOS transistor QP1 via the resistor R1.

Next, explanation follows regarding operation of the comparator circuit 10 according to the present exemplary embodiment. As previously described, a signal of H=16V or L=0V is input as the input voltage Vin of the comparator circuit 10. However, in the comparator circuit 10, the input voltage Vin is input to the drain of the diode-connected P-type MOS transistor QP1 via the resistor RI. When the input voltage Vin=L (=0V), the drain-source voltage Vds and a gate-source voltage Vgs of the P-type MOS transistor QP respectively remain at Vds=Vf, Vgs=Vf. Note that Vf is a threshold voltage of the P-type MOS transistor QP1. If for example the threshold voltage Vf is 0.7V, the remaining 15.3V (=VBB−Vf) is dropped at the resistor R1 (applied to the resistor R1). The voltage withstand conditions of the P-type MOS transistor QP1 applied with the input voltage Vin can therefore be satisfied.

Comparator circuits generally compare an input voltage against a reference voltage to determine whether the input voltage is L or H. The comparator circuit 10 reconverts the current Ia serving as an input current and the current Ib serving as a reference current to voltages in order to compare these voltages against each other. When this is performed in the present exemplary embodiment, this reconversion is to voltages compatible with the comparison section 15 operated by the low voltage power source VCC. Namely, the voltage Va serves as the input voltage of the comparison section 15 operated by the low voltage power source VCC, and the voltage Vb serves as the reference voltage of the comparison section 15. Note that there is no limitation thereto, and configuration may be made such that comparison is performed by a comparison section operated by the high voltage power source VBB.

Note that Equation 5 below can be obtained by substituting Equation 1 into Equation 3.

Va=VCC−(R3/R1)(VBB−Vin) (Equation 5)

Similarly, Equation 6 below can be obtained by substituting Equation 2 into Equation 4.

Vb=VCC−(R4/R2)(VBB−Vref) (Equation 6)

When R1=R2 and R3=R4 (when setting is made such that R1=R2, R3=R4), Equation 5 and Equation 6 may respectively be expressed as in Equation 7 and Equation 8 below.

Va=VCC−(R3/R1)(VBB−Vin) (Equation 7)

Vb=VCC−(R3/R1(VBB−Vref) (Equation 8)

Note that Equation 7 is a restatement of Equation 5.

As is clear when Equation 7 and Equation 8 are compared, all terms other than Vin and Vref are common terms, and therefore the magnitude relationship between Va and Vb is determined by the magnitude relationship between Vin and Vref. Namely, comparing Vin and Vref is equivalent to comparing Va and Yb, and both comparison results will match. As described above, the comparator circuit 10 according to the present exemplary embodiment enables a level shift from a high voltage power source to a low voltage power source to be performed in a simple manner.

Note that although an example has been given in which the current Ia flows uniformly in the input current generation section 11 and the first current-voltage conversion section 13, and the current Ib flows uniformly in the reference current generation section 12 and the second current-voltage conversion section 14 in the above exemplary embodiment, there is no limitation thereto. For example, a current that flows in the first current-voltage conversion section 13 may be smaller than the current la that flows in the input current generation section 11, and a current that flows in the second current-voltage conversion section 14 may be smaller than the current lb that flows in the reference current generation section 12.

1. A comparator circuit, comprising:
an input current generation section configured to generate an input current based on an input voltage;
a reference current generation section configured to generate a reference current based on a reference voltage,
a first current-voltage conversion section configured to convert the input current to a comparison-target voltage;
a second current-voltage conversion section configured to convert the reference current to a threshold voltage; and.
a comparison section configured to compare the comparison-target voltage against the threshold voltage,
the input current generation section including a first transistor having a gate and a drain that are connected together, and the input voltage being input to the drain of the first transistor via a resistor.

2. The comparator circuit of claim 1, wherein the input current generation section includes a second transistor that mirrors a current flowing in the first transistor to generate the input current.

3. The comparator circuit of claim 1, wherein:
the input current generation section and the reference current generation section are connected to a first power source having a first voltage; and
the first current-voltage conversion section, the second current-voltage conversion section, and the comparison section are connected to a second power source having a second voltage that is lower than the first voltage.

4. The comparator circuit of claim 1, wherein:
the first current-voltage conversion section performs conversion to the comparison-target voltage based on a current mirroring the input current; and
the second current-voltage conversion section performs conversion to the threshold voltage based on a current mirroring the reference current.
